(19) United States
(12) Patent Application Publication
(10) Pub. No.: US 2010/0126087 A1
(43) Pub. Date: May 27, 2010

(54) Plank Based Photovoltaic Conversion System

(76) Inventors: Joe Brescia, Alameda, CA (US); Mark Tofflemire, Alameda, CA (US)

Correspondence Address: Law Office of J. Nicholas Gross, Prof. Corp., 2030 ADDISON ST., SUITE 610, BERKELEY, CA, 94704, US

(21) Appl. No.: 12/618,468

(22) Filed: Nov. 13, 2009

Related U.S. Application Data
(63) Continuation-in-part of application No. 12/564,609, filed on Sep. 22, 2009.
Application No. 12/564,609 is a continuation-in-part of application No. 12/564,627, filed on Sep. 22, 2009.
Application No. 12/564,627 is a continuation of application No. 12/564,664, filed on Sep. 22, 2009.
Application No. 12/564,664 is a continuation-in-part of application No. 12/564,671, filed on Sep. 22, 2009.
Application No. 12/564,671 is a continuation-in-part of application No. 12/564,686, filed on Sep. 22, 2009.
Application No. 12/564,686 is a continuation of application No. 12/564,732, filed on Sep. 22, 2009.
Application No. 12/564,732 is a continuation-in-part of application No. 12/564,740, filed on Sep. 22, 2009.
Application No. 12/564,740 is a continuation of application No. 12/564,748, filed on Sep. 22, 2009.
Application No. 12/564,748 is a continuation of application No. 12/564,761, filed on Sep. 22, 2009.
Application No. 12/564,761 is a continuation of application No. 12/564,768, filed on Sep. 22, 2009.
Application No. 12/564,768 is a continuation-in-part of application No. 12/564,774, filed on Sep. 22, 2009.
Application No. 12/564,774 is a continuation-in-part of application No. 12/564,783, filed on Sep. 22, 2009.
(60) Provisional application No. 61/114,410, filed on Nov. 13, 2008.

(51) Int. Cl. E04D 13/18; H02G 15/013; H01L 31/042; H01L 31/048

(52) U.S. Cl. 52/173.3; 277/608; 136/244; 136/251

(57) ABSTRACT

A power generating system includes a series of interconnected photovoltaic plank units, each made of multiple PV panels secured to a building structure spandrel area. The PV planks are adapted to be readily mounted to reduce installation time and cost. Electrical power can be more advantageously generated from surface areas of building structures such as commercial garages, overpasses and similar concrete facades previously untapped for solar energy harvesting.

### RELATED APPLICATION DATA

The present application claims the benefit under 35 U.S.C. §119(e) of the priority date of Provisional Application Ser. No. 61/114,410 filed Nov. 13, 2008, which is hereby incorporated by reference. The application further claims priority to and is a continuation-in-part of the following applications, all of which are incorporated by reference herein:
Building Integrated Power Generating System; Ser. No. 12/564,609 (attorney docket number 2009-1);
UL Compliant Building Integrated Photovoltaic Conversion System; Ser. No. 12/564,627 (attorney docket number 2009-2);
Method of Operating Building Integrated Photovoltaic Conversion System Ser. No. 12/564,664 (attorney docket number 2009-3);
Building Integrated Photovoltaic Conversion System Implemented With Integrated Control Management Units Ser. No. 12/564,671 (attorney docket number 2009-4);
Building Integrated Photovoltaic Conversion System Implemented In Both Vision and Spandrel Areas Ser. No. 12/564,686 (attorney docket number 2009-5);
Unitized Curtain Wall Module Adapted for Integrated Photovoltaic Conversion Module Ser. No. 12/564,732 (attorney docket number 2009-6);
Unitized Building Integrated Photovoltaic Conversion Module Ser. No. 12/564,740 (attorney docket number 2009-7);
Unitized Building Integrated Photovoltaic Conversion Module Adapted With Electrical Isolation and Grounding Ser. No. 12/564,748 (attorney docket number 2009-8);
Unitized Building Integrated Photovoltaic Conversion Module Adapted With Electrical Conduits Ser. No. 12/564,761 (attorney docket number 2009-9);
Integrated Electrical Conduit for Solar PV System; Ser. No. 12/564,768 (attorney docket number 2009-10);
Electrical Raceway for Building Integrated Solar PV System; Ser. No. 12/564,774 (attorney docket number 2009-11)
Method of Assembling Building Integrated Photovoltaic Conversion System; Ser. No. 12/564,783 (attorney docket number 2009-12);

### FIELD OF THE INVENTION

The present invention relates to modular photovoltaic power generating units, particularly units which can be mounted on building structures either directly or as part of an integrated photovoltaic plank.

### BACKGROUND

Photovoltaic (or PV) devices and systems are well-known in the art, as noted in prior filings by the present inventor. Recently a building integrated photovoltaic system has been presented by the applicant based on a so-called unitized curtain wall module. This module is particularly adapted for use as part of an aesthetic building exterior or shell.

There are many building installations, however, which do not use or require an aesthetic shell. It would be desirable nonetheless to add vertically (or sloped) hung PV power generating systems to such structures in an efficient and economic fashion. To date, the bulk of approaches for integrating PV into structures such as garages, bridges, overpasses, etc., require that the system be constructed entirely at the site from individual panels. The frame is built first, again from conventional aluminum type racking, and mounted (typically) into a spandrel area (i.e., such as in a concrete surface between parking levels in a parking garage). The individual panels are then mounted and electrically coupled to each other and, ultimately, to an inverter. While the process is relatively straightforward, it nonetheless suffers from inefficiencies and excessive costs resulting from the use of components that must be assembled for the most part onsite.

### SUMMARY OF THE INVENTION

An object of the present invention, therefore, is to reduce and/or overcome the aforementioned limitations of the prior art.

An aspect of the invention therefore concerns PV power generating systems and methods of assembling/manufacturing the same in installations such as commercial parking garages and similar structures offering largely untapped energy conversion potential;

Another aspect of the invention concerns a PV plank unit that can be easily installed in such environements/application.

Finally, other aspects of the inventions will be apparent to those skilled in the art from the detailed disclosure that follows.

It will be understood from the Detailed Description that the inventions can be implemented in a multitude of different embodiments. Furthermore, it will be readily appreciated by skilled artisans that such different embodiments will likely include only one or more of the aforementioned aspects or objects of the present inventions. Thus, the absence of one or more of such characteristics in any particular embodiment should not be construed as limiting the scope of the present inventions. While described in the context of a power generating array, it will be apparent to those skilled in the art that the present teachings could be used in any number of applications.

### DESCRIPTION OF THE DRAWINGS

FIG. 1 illustrates a preferred embodiment of a photovoltaic power generating system implemented in the form of a PV plank that is attached to the side of a building structure;

FIG. 2A shows a side perspective of a preferred embodiment of a PV power generating system including a PV plank of the present invention as it is typically mounted on a building structure;

FIGS. 2B-2C are expanded depictions of a head panel section and still panel section respectively of an assembled PV generating system.

### DETAILED DESCRIPTION

The present invention generally incorporates conventional photovoltaic panels or modules into “planks” which include a plurality of energy generating modules preferably pre-fabricated and constructed as 20-26 foot (+/−) units which can be mounted on the vertical sides of structures like buildings or especially parking garages. The planks preferably include a frame, but it is not strictly necessary. In some embodiments the planks may be adapted to serve a structural support role as well for other building elements.

The energy generating modules also preferably include integrated control modules such as referred to in the earlier disclosures noted above. In this form the PV system can be efficiently and cost effectively deployed because the tasks of constructing/assembling the planks and mounting them are separated and optimized.

Thus a PV subsystem can be assembled in the form of a PV plank in a controlled setting based on linking multiple panels (such as 3, 4, etc., depending on the overall size of such panel) together. At the installation site, the building can be prepared in advance with appropriate ties/holes, and/or other similar mounting mechanisms. The PV planks can then be delivered and mounted quickly and efficiently, reducing the overall installation time, cost and inconvenience to the site owner, and in a much safer manner.

Different configurations of the planks and output options can be employed depending on the site specifics. For example a number of planks could be mounted either parallel to a wall or “kicked out” (at more or less 30 degrees to enhance harvest). The output of the system could either be grid tied OR holes could be drilled through the wall and proper mechanisms tied into it to make it a hybrid vehicle charging station.

In such installations the PV planks typically do not require UL rating, but the bulk of the components used are nonetheless UL rated. If UL rating is required for the mounting system, this can be done relatively easily using well-known grounding techniques.

The PV planks are preferably pre-panelized in a controlled shop and hauled out to a parking structure (for example) and are affixed using a simple clipping system. Since the bulk of the work is done in the shop, the entire structure can be assembled in a very short duration onsite.

As with BIPV modules described in our prior related cases, an srt type component (wire way/raceway) is preferably included in the plank so that plank to plank hookups can be very quick. As referred to above individual control modules and dc bussing or micro inversion is preferably used to achieve module to module management. For further details on such structures please refer to the related applications discussed above.

The invention could be used to add PV power systems to vertical or near vertical surfaces on any built structure, particularly spandrel areas on buildings with precast spandrels. Furthermore it could be It could be run continuously on elevated structures like those used by public transportation systems (such as the Bay Area Rapid Transit—BART) elevated lines, on bridges, and similar structures. Accordingly the wide variety of site options means that there are thousands of venues in the built environment where the inventive PV planks could be deployed with minimal expertise and cost. As PV prices/watt come down, the labor cost becomes a much more important component; thus the invention affords a mechanism for both minimizing labor cost and deployment durations.

### Specific Details of Preferred Embodiment

In a conventional PV system mounted on a building structure, PV panels, wiring, controls, rack/support, etc. are all assembled on site and then plugged into the inverter/storage mechanisms. In the case of a preferred unitized PV plank as described herein the PV plank units are preferably each ‘plug and play’—each unit mates into and is electrically coupled to its adjacent unit to form part of a solar array.

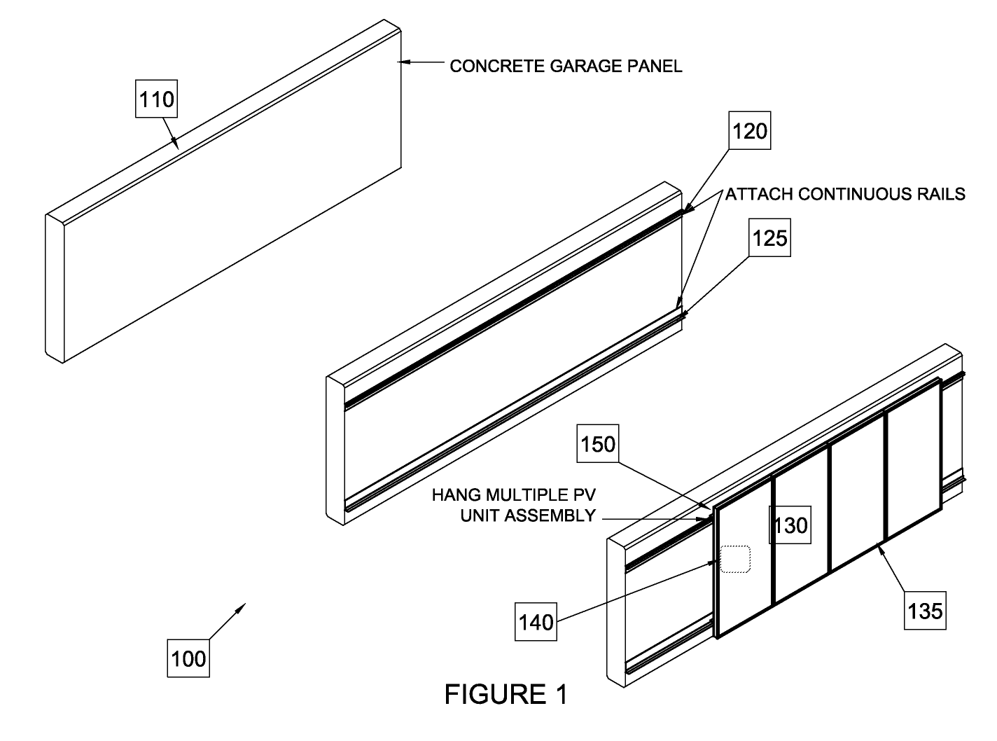

In a preferred embodiment the invention is used preferably in cladding at least part of a vertical spandrel portion of a building structure. As seen in FIG. 1 a concrete panel area 110 of a building structure is used to mount a PV system 100. A set of attachment tracks/rails 120 and 125 for hanging the PV planks are also attached to area 110, which again is preferably a concrete spandrel but it will be understood that the covered areas may include other compositions. All that is required is that it be capable of supporting a load imposed by PV planks 150.

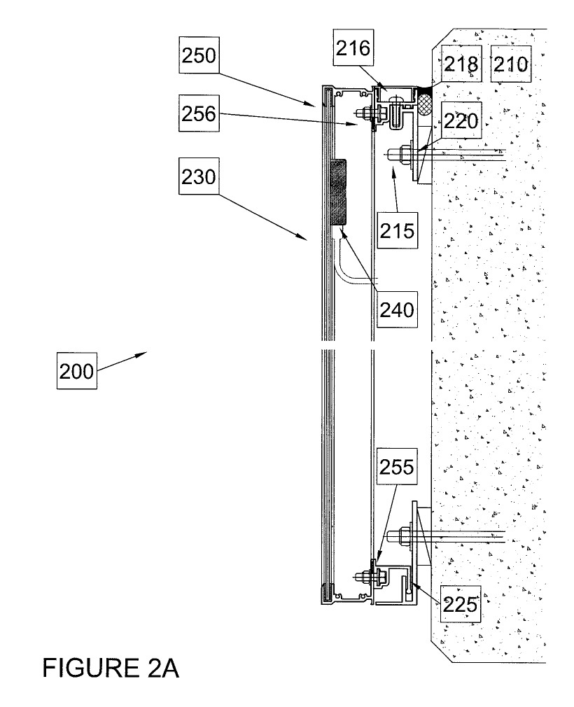

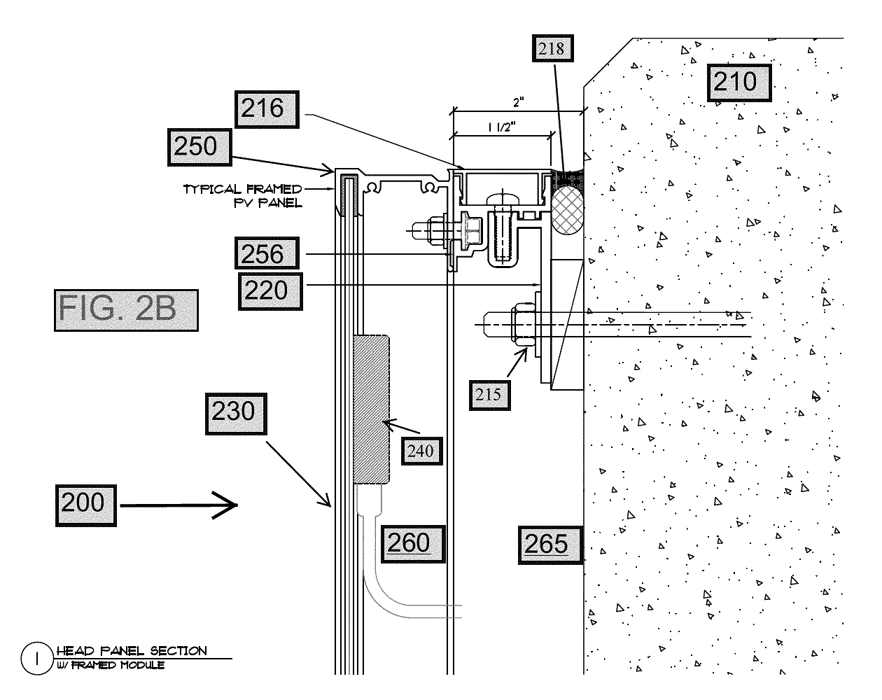

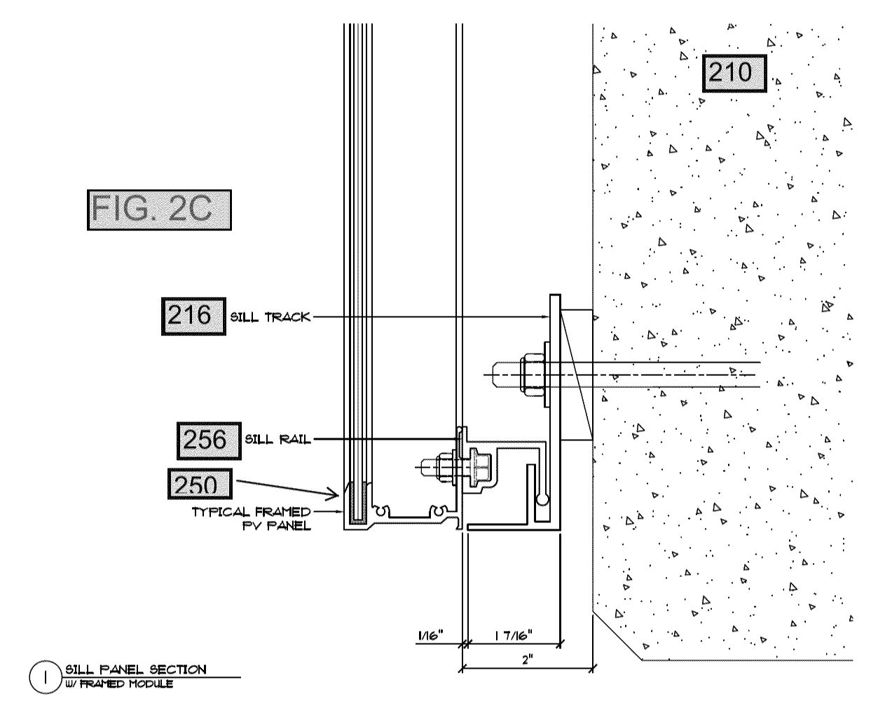

As alluded to earlier, PV planks 150 include a plurality of PV panels 130, each preferably with an associated control unit 140, and mounted within a frame member 135. The planks 150 are mounted on rails/tracks 120/125 where they are securely fastened as noted and discussed below in connection with FIGS. 2A-2C. While a single plank 150 is shown in FIG. 1, it will be understood that a typical installation will consist of multiple planks 150 connected together in a row or other convenient arrangement depending on a desired output level.

An expanded cross section of system 100 is depicted in FIGS. 2A-2C. In this figure, like numbered elements are intended to correspond to their counterparts in FIG. 1 unless otherwise noted. Thus in FIG. 2A, a mounting mechanism is attached to concrete panel 210 through a series of ties 215 which are preferably embedded into panel material 210 to fasten/secure a top head track 220 and a bottom sill track 225. An additional conventional gasket 218 is employed to seal an interior cavity 260 of the PV system from water and other intrusions. This latter cavity can be used as an electrical conduit to route DC cabling, including power and control signals between the PV panels and interconnected planks. Again it will be understood that in some installations other types of materials may be transported in this region using any convenient form of conduiting.

A PV plank 250 as noted earlier includes a plurality of PV panels 230 which are integrated with (or within) a frame member 235. The frame member 235 includes both a top head track 256 and a bottom sill track 255, which interlocks and mates mechanically with corresponding sill units 220/225 discussed above. Thus the mechanism for mounting the PV planks 250 is extremely simple and relies on simple mechanical mounting. The framing members 235 are preferably secured within the track/rail channels using screws or other similar fastener as shown. Other techniques could be employed of course depending on a desired cost/performance, material restrictions of the panel area 210, the structure of PV plank 250, etc.

A cavity 265 is defined by the body of framing member 235 and the front PV panel 230. In this cavity is situated a control module 240 which can be associated with each individual panel or on a larger aggregate plank level to control/contain a power output of the plank. In a preferred embodiment this control module is one of those discussed in our prior related applications referenced above. The cavity 265 can thus act as a form of integrated raceway for routing power and control signals between panels and other planks (not shown).

A head rail cover 216 sits atop the head rail 256 to further seal and fasten the plank to the mounting mechanism. This cover can be made of any suitable material, including plastic, metal, fiberglass etc.

As noted earlier the output of an array of PV planks 250 is preferably connected to the building electrical system, typically in the main distribution area, where it can be used to offset consumption of electrical power or feed power into the utility grid. In some instances additional routing can be done on a plank basis to drill holes (not shown) through concrete panel 210 to offer other DC and AC outlets for charging electrical devices, transportation vehicles, etc. The form of the output, including voltage levels, current levels, etc., can be tailored as needed for any particular application. Furthermore if desired a conventional battery electrical storage system can be employed in some cases to provide back-up power if desired. By utilizing previously unproductive space, the invention can add value to existing properties by making them more cost-effective, attractive to environmentally conscious tenants, and so on.

The invention is further attractive because it uses existing building structures for structural support, thus saving materials and labor. The integration of the PV modules within the planks results in a more cost efficient product that requires much less labor to install. Finally many of the raw materials of the PV system, including the frames, rails, etc., may be made of recycled aluminum or similar products, thus resulting in far less environmental impact.

The above descriptions are intended as merely illustrative embodiments of the proposed inventions. It is understood that the protection afforded the present invention also comprehends and extends to embodiments different from those above, but which fall within the scope of the present claims.

What is claimed is:

1. A power generating system adapted to be mounted on a building structure comprising:
an array of one or more interconnected unitized photovoltaic (PV) plank units, each of such unitized PV planks including:
a rigid frame member;
a plurality of individual PV modules integrated and interconnected within said frame member;
wherein said rigid frame member borders and encloses at least an edge and back portion of said individual PV modules to define a wiring conduit;
a mounting mechanism adapted to secure said rigid frame member to a surface of a building structure;
wherein the unitized PV planks can be mounted on a vertical surface of said building structure.

2. The system of claim 1 wherein said array is a single row of multiple interconnected PV plank units.

3. The system of claim 1 wherein a first side of said mounting mechanism interlocks with said PV planks, and a second opposing side is bolted to said building structure.

4. The system of claim 1 wherein said structure is one of a multi-story garage, a highway overpass, a train overpass, or a bridge.

5. The system of claim 1 wherein each of individual PV modules includes an integrated power controller to regulate an output of such module and counter effects of shading.

6. The system of claim 1 further including a track cover and a sealer adapted to seal an interior cavity formed between said PV plank and said mounting mechanism.

7. The system of claim 1 wherein a power output of the PV plank units is routed to a grid and/or to a charging station within said building structure.

8. A photovoltaic (PV) plank unit adapted for use in a vertical portion of a building structure and comprising:
a rigid frame member;
said rigid frame member having a plank shape and enclosing a plurality of individual PV modules;
said rigid frame member and plurality of individual PV modules being arranged to define an integrated enclosed raceway portion for carrying electrical wiring for said plurality of individual PV modules;
wherein the unitized PV plank is adapted to be hung on rails of a building mounting structure.

9. The photovoltaic plank unit of claim 8 wherein said rigid frame member is made of aluminum.

10. The photovoltaic plank unit of claim 8 wherein said PV modules include an integrated controller for controlling a power output.

11. The photovoltaic plank unit of claim 8 wherein said integrated controller is mounted directly on a PV panel for said individual PV modules.

12. A unitized photovoltaic (PV) plank unit adapted for use in a vertical portion of a building structure and comprising:
a rigid frame member defining an enclosure for a plurality of individual contiguously mounted PV modules;
the rigid frame member further having a front surface with an edge portion which retains said plurality of individual contiguously mounted PV modules;
the rigid frame member further having a back surface which encloses said plurality of individual PV modules and defines a sealed integrated raceway portion for carrying electrical wiring for said plurality of individual PV modules;
at least one electrical control module mounted on said plurality of individual PV modules for controlling a power output of the PV plank unit;
an electrical cable coupled to said electrical control module and said plurality of individual PV modules, which cable is adapted to carry both a power output and control lines for such modules;
said back surface of said rigid frame member including a top rail and a bottom rail adapted to be hung on sills of a building mounting structure.

13. The unitized photovoltaic (PV) plank unit of claim 12 wherein said top rail and said bottom rail include an interlocking mechanism for mating with said sills.

14. The unitized photovoltaic (PV) plank unit of claim 12 wherein said rigid frame member is substantially waterproof.

15. The unitized photovoltaic (PV) plank unit of claim 12 wherein a body of said rigid frame member includes an opening for communicating said electrical cable to a second PV plank unit.

16. The unitized photovoltaic (PV) plank unit of claim 12 wherein at least four (4) separate individual PV panels are mounted within said frame member.

17. The unitized photovoltaic (PV) plank unit of claim 12 wherein the plank unit is self-contained such that it can be mounted to a mounting mechanism on a building structure and operated without further electrical components.

18. The unitized photovoltaic (PV) plank unit of claim 12 wherein the plank unit interlocks with a mounting mechanism on a building structure to define a substantially sealed conduit.

19. The unitized photovoltaic (PV) plank unit of claim 12 wherein said rigid frame member and said sills are made of a recycled metallic material.

20. The unitized photovoltaic (PV) plank unit of claim 12 further including a rail cover adapted to cover said top rail.
